(19) United States
(12) Patent Application Publication
(10) Pub. No.: US 2013/0251916 A1
(43) Pub. Date: Sep. 26, 2013

(54) SUCTION VALVE IN A PLASMA COATING APPARATUS

(71) Applicant: KRONES AG, Neutraubling (DE)

(72) Inventors: Jochen Krueger, Hagelstadt (DE); Andreas Kraus, Regensburg (DE)

(73) Assignee: KRONES AG, Neutraubling (DE)

(21) Appl. No.: 13/755,745

(22) Filed: Jan. 31, 2013

(30) Foreign Application Priority Data
Mar. 23, 2012 (DE) 10 2012 204 689.5

(51) Int. Cl. C23C 16/50

(52) U.S. Cl. CPC C23C 16/50
USPC 427/569; 118/723 R

(57) ABSTRACT

The present disclosure relates to an apparatus for coating a container e.g. a plastic bottle, by means of a plasma treatment. The apparatus includes at least one gas lance for supplying process gas into the container, and at least one suction valve for sucking off air from the interior of the container. The suction valve has at least one recess, e.g. a centrally arranged one, for receiving or introducing the at least one gas lance into the container, and the suction valve has at least one grounded, gas-permeable, electrical shielding element. The at least one grounded, gas-permeable, electrical shielding element prevents and/or suppresses nearly entirely the ignition and/or burning of plasma in the suction valve.

### FIELD OF THE INVENTION

The present disclosure relates to apparatus and methods for coating a container by means of a plasma treatment.

### BACKGROUND

To reduce the permeability of container walls/walls of hollow bodies, e.g. in respect of undesired substances, it is advantageous to provide these walls with a barrier layer, for instance by the plasma-enhanced chemical vapor deposition (PECVD), as is described, for instance, in EP 0881197A2.

Such barrier layers are required, for instance, to reduce the transmission rates of gases through the plastic wall of a container. This allows, for instance, to minimize the loss of CO2 from the filled product or the introduction of oxygen into the product. Also, it is possible to protect the product against substances escaping from the container material, which may change the color or taste of the product.

For the coating of containers by means of a plasma treatment, e.g. the interior plasma coating of plastic bottles, inter alia, a so-called high-frequency plasma may be used in so-called low-pressure systems.

Initially, the interior of the container is evacuated to a pressure in the range of 1-10 Pa. Then, a process gas is introduced through a gas lance into the area of the surface to be coated, e.g. the interior of the container. The layer—the so-called precursor—is formed from the process gas and allows the pressure inside the container to rise to 10-30 Pa or more.

This gas or gas mixture may be transferred in part or in whole into a plasma state by means of electromagnetic radiation, e.g. microwaves or high frequency, e.g. at 13.56 MHz, or other electric fields and, at the same time, be decomposed into its components.

In this case, for instance, a high frequency irradiated by a flat electrode outside the container is coupled to an electrically conducting gas lance and, with good pressure conditions in the container between 10 and 30 Pa, ignites a plasma in the interior of the container to be coated.

Portions of the process gas supplied into the interior of the container through suitable bores in the gas lance react plasma-enhanced in the gas phase or on the surface of the substrate to be coated, e.g. the inner wall of a plastic bottle, and condense on this surface forming a closed layer.

To prevent the ignition of plasma outside the bottles, this region is subjected to a higher pressure, e.g. 3000 to 4000 Pa, as compared to the pressure inside the container. To this end, the container may be pressed against a valve through which the interior of the container is evacuated to the process pressure of 1-30 Pa.

A problem arising in practice is that the plasma may burn not only in the container, but in an undesired manner also in the suction valve. This plasma uses up an undefined and undefinable part of energy, which is then no longer available in the container to decompose the process gases. It is difficult, in this case, to compensate this loss of energy, for instance, by a higher high-frequency power because this may lead to higher voltages at the electrodes. These higher voltages may, again, result in plasma discharges outside the container, so that the electric power available in the container is further reduced.

Another problem are the temperatures and the reactive gases generated by the plasma in the valve. They make the process even more difficult as the valves have to be cooled down actively to protect them against damage. Moreover, the sealing materials in the valve are affected by the reactive gases and need to be replaced more often.

If the valves are made of a plastic material they constitute in principle, as far as the conditions are concerned, a geometric prolongation of the bottle opening. If high frequency is applied, a plasma is ignited there, however, just like in the container itself. If the valve is made of metal and the individual components are grounded a plasma may develop in the interior all the same, as a hollow cathode may thus be formed. Besides, such hollow cathode plasmas have a particularly intensive plasma density, heating up the valve components especially strongly and, thus, leading to damages.

It is, therefore, an object of the present disclosure to improve an apparatus for the coating of containers by means of a plasma treatment, for instance the coating of plastic bottles, in particular with respect to minimizing undesired plasma ignitions and/or plasma burning in the region of the container opening.

### SUMMARY

According to the disclosure this is achieved in some arrangements by an apparatus according to claim 1 and by a method according to claim 14. Advantageous embodiments and further developments are defined in the dependent claims.

An apparatus according to the disclosure for coating a container, e.g. a plastic bottle, by means of a plasma treatment may include at least one gas lance for supplying process gas into the container, and at least one suction valve for sucking off air or gas from the interior of the container.

The suction valve may have at least one recess, e.g. a centrally arranged one, for receiving or introducing the at least one gas lance into the container, and the suction valve may include at least one grounded, gas-permeable, electrical shielding element. The at least one grounded, gas-permeable, electrical shielding element is capable of preventing and/or suppressing nearly entirely the ignition and/or burning of plasma in the suction valve.

Avoiding or minimizing plasma ignitions and/or the burning of plasma in the suction valve has the advantage, inter alia, that the suction valve is thermally loaded to a smaller extent, for instance no active cooling is necessary, so that a longer service life of the suction valve can be obtained. Furthermore, minimizing undesired plasma ignitions and/or plasma burning processes in the suction valve or outside the container region to be coated has the advantage that an energy loss for the plasma used for the coating can be reduced.

The electrical shielding element around the at least one recess for receiving or introducing the at least one gas lance may have gas-permeable hollow body structures. Preferably, these gas-permeable hollow body structures may have average diameters which are equal to or smaller than the Debye length of the plasma generated during the coating so as to allow an effective electrical shielding effect in order to minimize plasma ignition processes and plasma burning processes in the suction valve.

The electrical shielding element may have a plurality of different structures. In particular, the electrical shielding element may be a gas-permeable, open-pored porous structure, with pores whose average pore diameter is, for instance, between 0.01 and 6 mm, preferably 3 and 4 mm.

In this connection, it is possible that this gas-permeable hollow body structure or, respectively, this gas-permeable, open-pored porous structure of the electrical shielding element may be made of a metallic foam, e.g. an aluminum foam, or of an electrically conducting ceramic foam, e.g. Al2O3/TiN, or of electrically conductive composite ceramics with carbon fibers, or of a plastic or polymer foam having electrically conductive properties, or of a combination of the aforementioned foams.

The electrical shielding element around the at least one recess for receiving or introducing the at least one gas lance may also have at least one meshed grid structure with average mesh diameters, for instance, between 0.01 and 6 mm, preferably 0.2 and 0.5 mm. It is, for instance, also conceivable that the suction valve includes a plurality of electrical shielding elements having a meshed grid structure which may be arranged in the suction valve in multiple layers with distances between 0.01 and 6 mm, preferably 0.5 and 1 mm, for instance, to prevent the plasma from being ignited and/or deposited between the layers.

In addition, it is conceivable that the electrical shielding element around the at least one recess for receiving or introducing the at least one gas lance is formed of concentrically arranged walls having radial intermediate partition walls, with average wall distances of the concentrically arranged walls ranging, for instance, between 0.01 and 6 mm, preferably 3 and 4 mm, and average distances of the radial intermediate partition walls, e.g. ranging between 0.01 and 6 mm, preferably 3 and 4 mm.

The electrical shielding element around the at least one recess for receiving or introducing the at least one gas lance may also be formed as a honeycomb structure, with average honeycomb diameters of the honeycomb tubes ranging, for instance, between 0.01 and 6 mm, preferably 3 and 4 mm.

The average length of the honeycomb tubes preferably should, in this case, be greater than the average honeycomb diameter of the honeycomb tubes. For instance, the average length of the honeycomb tubes may exceed the average honeycomb diameter of the honeycomb tubes by a factor of 4.0, 6.0, 10.0 or more, preferably 5 to 10. This has the advantage, inter alia, that the risk of a breakdown of the plasma along the longitudinal axis of the suction valve can be minimized.

The shapes of the cross-sections of the honeycomb tubes may be regular polygon shapes, e.g. a triangle, square, pentagon, hexagon, convex and/or non-convex inner wall shape, a star-shaped polygon shape, round shapes, e.g. a circular shape, elliptical shape, or a combination of the aforementioned shapes. However, hexagonal cross-sections are preferred so as to be able to obtain an optimized relationship between the honeycomb structure material, the honeycomb structure volume and the honeycomb structure stability.

Furthermore, also metal plates may be used as electrical shielding element, which may have a plurality of bores with average bore diameters of 0.01 to 6 mm, preferably 3 to 4 mm. The length of the bores may be a multiple of the average bore diameters, preferably exceed the average bore diameter by a factor of 5 to 10.

The electrical shielding element may be made of metal, e.g. aluminum, of electrically conductive ceramics, e.g. Al2O3/TiN, of electrically conductive composite ceramics with carbon fibers, of a plastic material having electrically conductive properties, or of a combination of the aforementioned materials.

The flow resistance of the suction valve when sucking off air or gas from the container primarily depends on the open cross-section of the suction valve, the frictional resistance on the inner wall of the suction valve and the air conduction in the valve. The rate at which the interior of the container can be evacuated to the desired process pressure is limited above all by the opening cross-section of the container itself.

Preferably, the opening cross-section of the suction valve may, therefore, have at least the same size as the opening cross-section of the container. Preferably, also the flow resistance of the suction valve during the evacuation may be equal to or smaller than the flow resistance through the container opening.

This has the advantage that the interior of the container can be evacuated to a desired process pressure, e.g. between 1 and 30 Pa, sufficiently fast, e.g. in less than 500 ms, so as to allow the treatment or coating of the containers at the speed at which they travel through the production process, e.g. on conveyor belts or holding clamps of a carousel.

The electrical shielding element may be formed of one piece or multiple pieces and cover in respect of its height at least 10%, 20%, 30% or 60% or more of the height of the suction valve.

However, the suction valve may also include a plurality of electrical shielding elements and cover in the sum of the heights of the individual electrical shielding elements at least 10%, 20%, 30% or 60% or more of the height of the suction valve. The electrical shielding element may, for example, be formed of a combination of a honeycomb structure, an open-pored porous foam or a grid, whereby the vertical distance between the different parts may be smaller than 1, 2 mm, preferably smaller than 0.5 mm.

In a method according to the disclosure for coating a container, e.g. a plastic bottle, by means of a plasma treatment a gas lance may be introduced through a recess of a suction valve sitting on the container opening into the interior of the container. Through the suction valve the interior of the container can be evacuated to a process pressure, for instance, of 1 to 30 Pa. Inside the container a process gas, which is supplied by the gas lance, can be transformed in part or in whole into a plasma, and the interior of the container can be coated by means of a plasma-enhanced chemical vapor deposition, e.g. with a gas barrier layer. One or more electrical shielding element(s) located in the suction valve prevent(s) and/or suppress(es) nearly entirely an ignition and/or burning of plasma in the suction valve or in a region not to be coated.

### BRIEF DESCRIPTION OF THE DRAWINGS

The accompanying figures show by way of example:

FIG. 1 shows a container with a gas lance and a suction valve;

FIG. 2 shows a suction valve;

FIG. 3 shows a suction valve;

FIG. 4 shows a honeycomb structure;

FIG. 5A shows a first exemplary cross-section for an electrical shielding element;

FIG. 5B shows a second exemplary cross-section for an electrical shielding element;

FIG. 5C shows a third exemplary cross-section for an electrical shielding element; and

FIG. 5D shows a fourth exemplary cross-section for an electrical shielding element.

### DETAILED DESCRIPTION

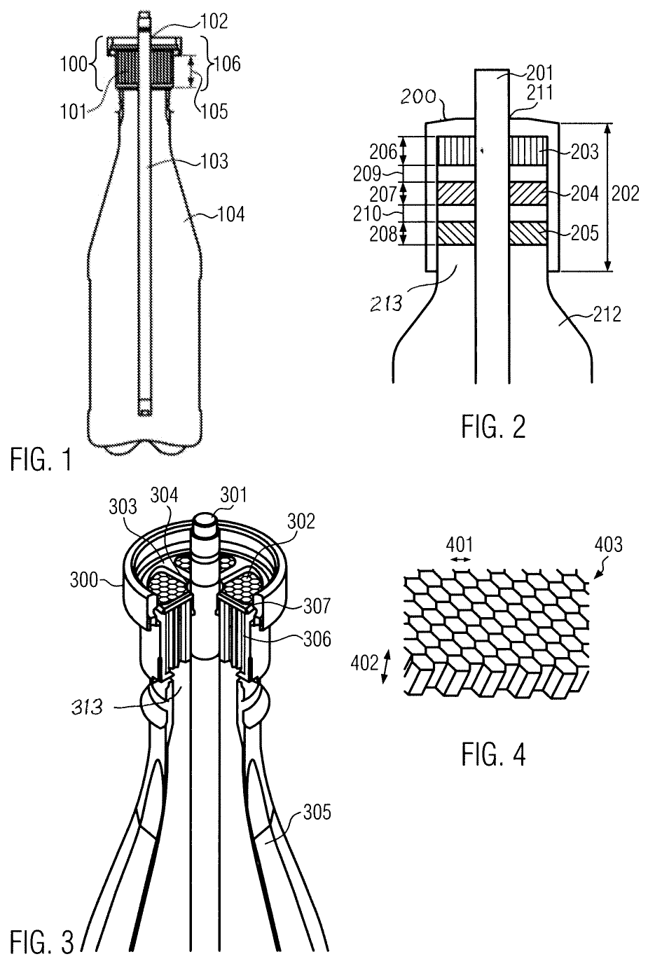

FIG. 1 shows by way of example a container 104 including a suction valve 100. A gas lance 103 may be introduced into the container 104 through a recess 102 in the suction valve 100. The suction valve 100 may have an electrical shielding element 101, which has a height 105 that may extend, for instance, across nearly the entire height 106 of the suction valve 100.

FIG. 2 shows by way of example the opening 213 of a container 212 with a suction valve 200 sitting on same. A gas lance 201 may be introduced through a recess 211 of the suction valve 200 into the container 212. The suction valve 200 may comprise a plurality of electrical shielding elements 203, 204, 205, which may have different heights 206, 207 and 208 and distances 209, 210 from each other, e.g. distances 209, 210 between 0.01 and 6 mm, preferably 0.5 and 1 mm. The sum of the individual heights 206, 207 and 208 of the electrical shielding elements 203, 204, 205 can cover at least 10%, 20%, 30% or 60% or more of the height 202 of the suction valve 200.

Moreover, the electrical shielding elements 203, 204, 205 may be different from each other in respect of material and structure. For instance, the electrical shielding element 205 may be made of an open-pored porous metal foam, the electrical shielding element 204 may be made of a honeycomb structure, and the electrical shielding element 203 may be made of a grid structure.

FIG. 3 shows by way of example the opening 313 of a container 305 with a suction valve 300 sitting thereon. A gas lance 301 can be introduced through a recess 304 of the suction valve 300 into the container 305. The gas lance 301 may be additionally fixed by a holder 303. The suction valve 300 may comprise an electrical shielding element 302 formed of a honeycomb structure. The average length of the honeycomb tubes 306 may be greater than the honeycomb diameter of the honeycomb tubes 306 by a factor of 1.5, 2.0, 4.0, 6.0, 10.0 or more, preferably 5 to 10. The honeycomb diameter 307 of the honeycomb tubes 306 may be between 0.01 and 6 mm, preferably between 3 and 4 mm. See in this respect also FIG. 4, illustrating by way of example the honeycomb diameter 401 and the length 402 of a honeycomb tube in a honeycomb structure 403.

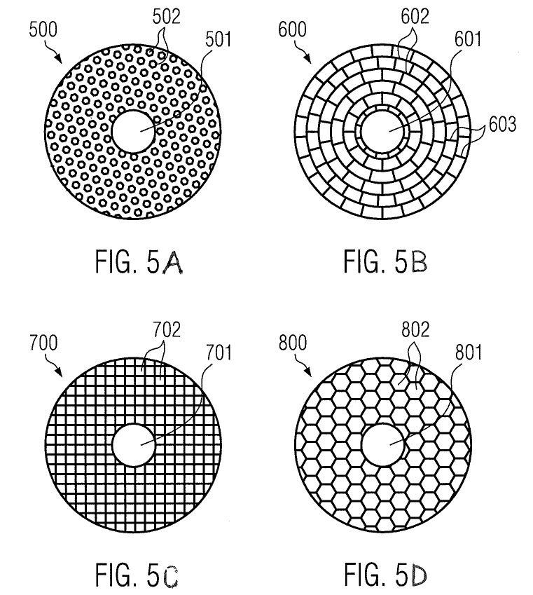

FIGS. 5A, 5B, 5C, 5D show by way of example different cross-sectional shapes of different exemplary electrical shielding elements.

In FIG. 5A the electrical shielding element 500 has, for instance, an open-pored porous structure around the recess 501, whereby the pores 502 may have average pore diameters between 0.01 and 6 mm, preferably between 3 and 4 mm.

In FIG. 5B the electrical shielding element 600 has, for instance, a structure of concentric walls 602 with radial intermediate partition walls 603 around the recess 601, whereby the average distances between the concentric walls 602 and the radial intermediate partition walls 603 may each be between 0.01 and 6 mm, preferably between 3 and 4 mm.

In FIG. 5C the electrical shielding element 700 has, for instance, a grid structure with meshes 702 around the recess 701 whose average mesh diameter may range between 0.01 and 6 mm, preferably between 0.2 and 0.5 mm. The geometry of the meshes 702 may be a regular or an irregular one.

FIG. 5D shows by way of example an electrical shielding element 800 having a honeycomb structure around the recess 801, with average honeycomb diameters of the honeycomb tubes 802 which may range, for instance, between 0.01 and 6 mm, preferably between 3 and 4 mm. The honeycomb cross-section may be hexagonal, as is illustrated. However, other cross-sectional shapes are possible as well, such as regular polygon shapes, e.g. a triangle, square, pentagonal, convex and/or non-convex inner wall shape, a star-shaped polygon shape, round shapes, e.g. a circular shape, elliptical shape, or a combination of the aforementioned shapes.

Structures having hexagonal honeycomb cross-sections are preferred, inter alia, in order to advantageously obtain an optimal relationship between the honeycomb tube opening cross-section and the honeycomb tube wall cross-section, and, for instance, in order to allow the easy production of the honeycomb structure by means of folding and joining methods, e.g. of a film material.

It is noted that the exemplary circular outer contour of the electrical shielding element and the suction valve, respectively, is a consequence of the adaptation to the usually circular container opening shape. It is, therefore, easily possible to also adapt the geometry of the suction valve and the electrical shielding element to non-circular container openings, e.g. rectangular container openings.

1. An apparatus for coating a container, by means of a plasma treatment, comprising:
at least one gas lance for supplying process gas into the container,
a suction valve for sucking off air from the interior of the container,
wherein the suction valve has at least one recess, for receiving or introducing the gas lance into the container, and the suction valve has at least one grounded, gas-permeable, electrical shielding element, and the at least one grounded, gas-permeable, electrical shielding element suppresses nearly entirely the ignition and/or burning of plasma in the suction valve.

2. An apparatus according to claim 1, wherein the electrical shielding element around the at least one recess for receiving or introducing the at least one gas lance has an open-pored porous structure.

3. An apparatus according to claim 2, wherein the electrical shielding element is made of at least one or more of a metallic foam, an electrically conducting ceramic foam, electrically conductive composite ceramics with carbon fibers, and a plastic or polymer foam having electrically conductive properties.

4. An apparatus according to claim 1, wherein the electrical shielding element around the at least one recess for receiving or introducing the at least one gas lance has at least one meshed grid structure with average mesh diameters, between 0.01 and 6 mm.

5. An apparatus according to claim 1, wherein the electrical shielding element around the at least one recess for receiving or introducing the at least one gas lance is comprised of concentrically arranged walls having a plurality of radial intermediate partition walls.

6. An apparatus according to claim 1, wherein the electrical shielding element around the at least one recess for receiving or introducing the at least one gas lance has a honeycomb structure comprising a plurality of honeycomb tubes.

7. An apparatus according to claim 6, wherein the average length of the honeycomb tubes is greater than the average honeycomb diameter of the honeycomb tubes.

8. An apparatus according to claim 6, wherein the cross-sections of the honeycomb tubes have regular polygon shapes, round shapes, or a combination of regular polygon shapes and round shapes.

9. An apparatus according to claim 1, wherein the electrical shielding element is made of one or more of electrically conductive ceramics, electrically conductive composite ceramics with carbon fibers, a metal, of and a plastic material having electrically conductive properties.

10. An apparatus according to claim 1, wherein the flow resistance of the suction valve when sucking off air through an opening in the container is equal to or smaller than the flow resistance through the opening.

11. An apparatus according to claim 1, wherein the suction valve is configured to allow the interior of the container to be evacuated to a desired process pressure in less than 500 ms.

12. An apparatus according to claim 1, wherein the electrical shielding element covers in respect of its height at least 10% of the height of the suction valve.

13. An apparatus according to claim 1, wherein the suction valve comprises a combination of a plurality of different forms of electrical shielding elements selected from the group of forms including a honeycomb structure, a structure of concentric walls with radial intermediate partition walls, a grid structure and an open-pored porous foam.

14. A method for coating a container by means of a plasma treatment, comprising the steps of:
introducing a gas lance into the interior of the container, the gas lance being passed through or received in a recess in a suction valve sitting on the container opening;
evacuating the interior of the container to a process pressure of 1 Pa to 30 Pa;
supplying process gas into the interior of the container by the gas lance; and
plasma-enhanced coating of the interior of the container by chemical vapor deposition, wherein at least one electrical shielding element located in the suction valve prevents nearly entirely ignition and/or burning of plasma in the suction valve or in a region of the container not to be coated.

15. An apparatus according to claim 1, wherein the container comprises a plastic bottle.

16. An apparatus according to claim 1, wherein the recess is centrally arranged on the suction valve.

17. An apparatus according to claim 2, wherein the pores have an average pore diameter between 0.01 and 6 mm.

18. An apparatus according to claim 5, wherein, average distances between adjacent concentric walls range between 0.01 mm and 6 mm, and average distances of the radial intermediate partition walls range between 0.01 mm and 6 mm.

19. An apparatus according to claim 6, wherein the honeycomb tubes have an average honeycomb diameter ranging between 0.01 mm and 6 mm.

20. An apparatus according to claim 7, wherein the average length of the honeycomb tubes exceeds the average honeycomb diameter of the honeycomb tubes by a factor of at least 1.5.

21. An apparatus according to claim 20, wherein the average length of the honeycomb tubes exceeds the average honeycomb diameter of the honeycomb tubes by a factor of 5 to 10.

22. An apparatus according to claim 8, wherein the regular polygon shapes include one or more of a triangle, square, pentagon, hexagon, convex and/or non-convex inner wall shape, and a star-shaped polygon shape.

23. An apparatus according to claim 8, wherein the round shapes, include one or more of a circular shape, and an elliptical shape.

24. An apparatus according to claim 11, wherein the desired process pressure is between 1 Pa and 30 Pa.
